(19) United States
(12) Patent Application Publication
(10) Pub. No.: US 2008/0111599 A1
(43) Pub. Date: May 15, 2008

(54) Wideband dual-loop data recovery DLL architecture

(76) Inventor: Rajendran Nair, Gilbert, AZ (US)

Correspondence Address: Rajendran Nair, ComLSI Inc., 3838 E. Encinas Ave., Gilbert, AZ, 85234, US

(21) Appl. No.: 11/598,435

(22) Filed: Nov. 14, 2006

(51) Int. Cl. H03L 7/06

(52) U.S. Cl. 327/158

(57) ABSTRACT

A novel wideband, low bit-error rate, dual-loop data recovery architecture is disclosed. The architecture employs a wideband clock receiver PLL that receives a synchronizing clock and generates the necessary high frequency clock for data transmission and recovery. The wideband PLL translates operating frequency information into a current reference that is transmitted to all data receiver channels. This current reference is employed to control a matched open-loop delay line at each data receiver. The phase clocks generated by this matched delay line maintain their angular relationship with respect to the primary clock transmitted by the wideband PLL over the entire range of frequencies. A bang-bang algorithm employed in the data receivers renders any delay mismatch between data receiver delay lines and the primary PLL inconsequential. A preferred embodiment employs phase interpolators to generate 16 phase clocks within each primary high-frequency clock cycle, and the bang-bang algorithm selects an optimal data sampling edge for each data channel. The combination of a low-jitter primary PLL and an accurate sampling-clock placement algorithm ensures very low bit error rates in this data recover architecture, enabling significantly longer communication distances over cables.

### TECHNICAL FIELD OF THE INVENTION

Embodiments of the invention relate to electronic circuitry commonly employed to receive data and binary signals transmitted over lengths of interconnect from other electronic circuits, devices and systems. Such circuitry falls under the category of Data Communication Circuits.

### BACKGROUND & PRIOR ART

Phase-locked loops (PLL's) and delay-locked loops (DLL's) are commonly employed in clock and data recovery functions of data communication systems. PLL's are often employed for extracting a clock signal out of encoded symbol streams such as 8b/10b encoded data. Clock and Data Recovery (CDR) architectures often use PLL's because they not only assist in recovering the clock signal embedded within the data stream, but also provide a constant, tracking phase relationship with respect to data transitions, enabling accurate sampling of the received data. This is particularly important when data is transmitted over long distances, or over lossy interconnect that attenuate and distort the transmitted signals substantially where accurate sampling clock placement is essential to recovering data symbols distorted by attenuation, inter-symbol interference (ISI) and data channel-to-channel crosstalk. Such PLL's are called Clock-Extraction PLL's in the art and find common use in optoelectronic data communication systems and electronic data transmission systems operating at very high data rates.

In data communication systems where the operating bit-rate remains essentially constant, DLL's may be used in place of PLL's, since clock recovery is not an essential function, while accurate phase positioning is desired for error-free data sampling. DLL's are also useful in generating multiple edges within a clock period that can be employed to transmit and receive multiple data bits within one clock period. DLL's have advantages in their inherent simplicity and consequent stability; they also do not generate as much jitter as PLL's using high-gain voltage controlled oscillators (VCO's) do, or transfer as much reference clock energy into the output clock signal.

In certain applications, as for example digital video interfaces (DVI) and high-definition multi-media interfaces (HDMI), due principally to backward compatibility requirements, interface links are required to be able to transmit data over a wide range of data transmission rates. In DVI links, for example, data and clock are transmitted on separate channels (twisted wire pairs in the context of cable interconnect) of a cable link, with the data transmission rate being 10 times the clock frequency, while the clock frequency may also vary over as much as a decade in range, from 25 MHz up to 250 MHz. Such links that transmit a clock along with data channels are termed “Source Synchronous” links. These links often require a PLL for de-jittering purposes as well as for the synthesis of higher frequency sampling clock employed to recover data. Additionally, since video data is transmitted over cables of significant length (10 meters or more, typically), de-skewing of the data channels is essential both for accurate data sampling and for re-alignment of the bit-streams with each other. Depending upon the extent of length mismatches between data channels, channel-to-channel skew may be less than, or substantially greater than a single data bit period. In order to be able to accurately sample a skewed data channel, it is important to be able to control the placement of a sampling clock signal within a small fraction of a data bit cell.

Prior art including chips from fables semiconductor company Silicon Image has successfully addressed the wide dynamic range requirement and skewed data sampling problem through the use of “Oversampling”, a technique that has also been applied to other high-speed serial data links such as the Universal Serial Bus (USB) and Serial-ATA. Oversampling is an architecture that samples data streams at a multiple of the data bit rate, and votes with values of the successive samples obtained in order to determine a digital bit value at any given point in time. A minimum number of samples per bit cell (one data bit period) is typically 3. This architecture avoids the use of delay-locked loops, and is “digital” in nature, thereby capable of high speeds while being simple in implementation as well. Yet, with only 3 samples in a bit-cell, there is a finite probability of error in the recognition of each bit cell, particularly when the data signals received are highly distorted. As shown in reference [1], there is a trade-off between clock quality, signal-to-noise ratio (SNR) and bit error probability in the two data recovery architectures. The analysis shows that at lower signal to noise ratio values, and with low jitter, extraction (a single sample technique) has a lower probability of bit error. The oversampling architecture is therefore not desirable for link implementations at high frequencies and over long lengths, and a need exists for another suitable architecture.

Whereas dual-loop clock and data recovery architectures do exist in the art, an architecture that combines a primary wideband PLL with tracking, wideband, open-loop data channel DLL's, to the best knowledge of the author of this invention, is not currently disclosed. The prior art oversampling architecture continues to be scaled in frequency in order to provide required higher frequencies of operation and data rates (10.2 billion bits per second or Gbps across a link) as in the HDMI 1.3 standard. Binary signal transmission suffers from a need for substantially higher channel bandwidth as compared with analog transmission of the same data. The author believes that bit error rates will increase as link signal distortion worsens and signal to noise ratio degrades due to higher frequency of operation and/or greater lengths of links, leading to lower overall video quality. While this lower video quality may be masked to some extent by the ongoing transition to high-definition video, the need to improve product quality while reducing cost will require a transition to the arguably more accurate data recovery architecture disclosed.

### INVENTION SUMMARY

The invention employs a wideband PLL to receive the source clock and PLL-tracking DLL's and phase interpolators to generate frequency-tracking, multiple, sampling clock edges. Multi-phase clock distributions and their associated jitter are completely avoided in this architecture; a single PLL output clock is distributed to all data channel receivers and PLL-tracking DLL's. The DLL's obtain frequency information from the wideband PLL in the form of a reference current that enables their open-loop delay lines to track the period of the clock frequency generated. Carefully designed mixers and amplifiers minimize duty-cycle distortion and develop a significant number of sub-cycle sampling edges. The transmission of a frequency-tracking current from the clock-receiver PLL to all the data channels forces delay lines local to each data channel to ‘lock’ on to this frequency information and adjust their stage delay accordingly irrespective of process, voltage and temperature variation. By designing DLL delay stages to be identical or ratioed with respect to the delay stages of the PLL VCO, the delay stages of each local DLL track the PLL frequency closely despite the lack of feedback. Inaccuracies in this delay tracking are rendered inconsequential by a bang-bang data recovery loop that chooses an optimal sampling edge. A high-performance, low-jitter PLL and the accurate placement of a sampling edge within bit cells accomplished by this dual-loop architecture significantly minimize bit errors in data transmission while minimizing power and area usage through the use of open-loop data channel DLL's.

### BRIEF DESCRIPTION OF THE FIGURES

FIG. 1 illustrates a typical prior art dual-loop architecture.

FIG. 2 is an illustration of the invention dual-loop architecture.

FIG. 3 is an embodiment of the invention architecture illustrating the generation and use of frequency-tracking current reference signals.

FIG. 4 illustrates an embodiment of a frequency-tracking open-loop delay line

### DETAILED DESCRIPTION

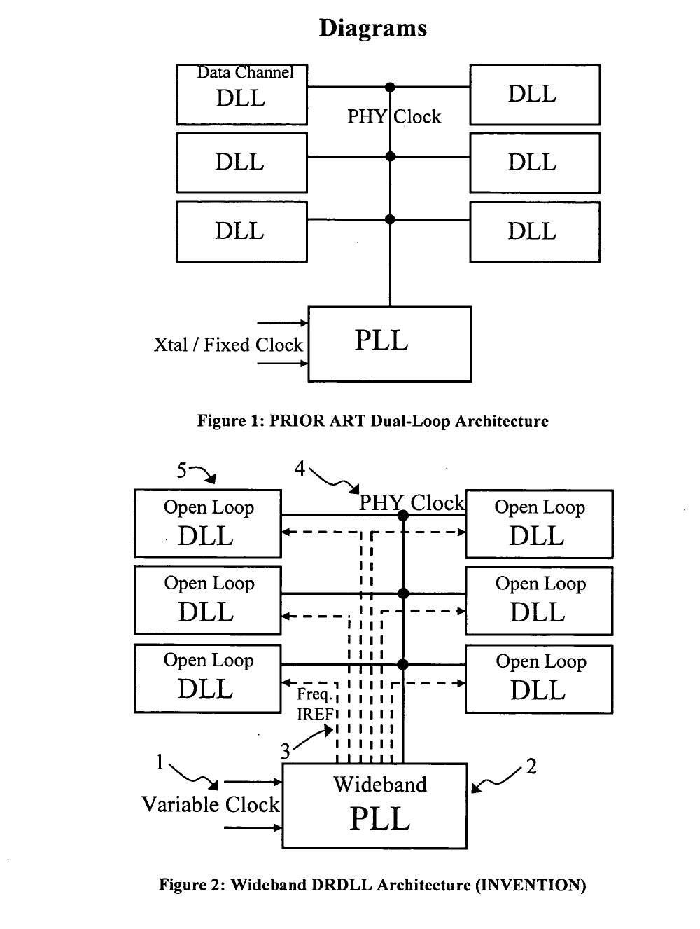

A prior art embodiment of a dual-loop data recovery architecture is illustrated in FIG. 1. As is typical in many multi-Gbps high-speed links employing dual-loop data recovery, a clock receiver phase-locked loop (PLL) receives a fixed clock signal and generates a necessary high-speed clock that is then distributed to multiple data transmit and receive channels. Each data channel contains an independent delay-locked loop (DLL) that adjusts the delay of each of its stages to be a fraction of the period of the clock generated and transmitted by the PLL. This is accomplished by means of feedback and high-speed phase comparisons between the PLL clock and the delayed DLL output clock. The stage outputs of the DLL are then either employed directly for oversampling, or are mixed to further generate more finely placed clock edges for the selection of an optimal edge to be used in data sampling. This prior art dual-loop architecture necessitates the use of a full DLL with a high-speed phase comparator and other circuits such as a charge pump and a loop filter in each data channel. This incurs corresponding area and power penalties. Additionally, loop-bandwidth interactions between the DLL and the primary PLL lead to clock jitter and consequent increased bit error rates (BER). Also, such fixed frequency architecture is not usable in a DVI/HDMI application that requires as much as a decade-wide range in operating frequency. In such an application, where the synchronizing clock is one-tenth of the link data rate, designing a PLL and a tracking DLL of appropriate loop bandwidths capable of the required range of frequencies, while feasible, is a complex and potentially expensive task.

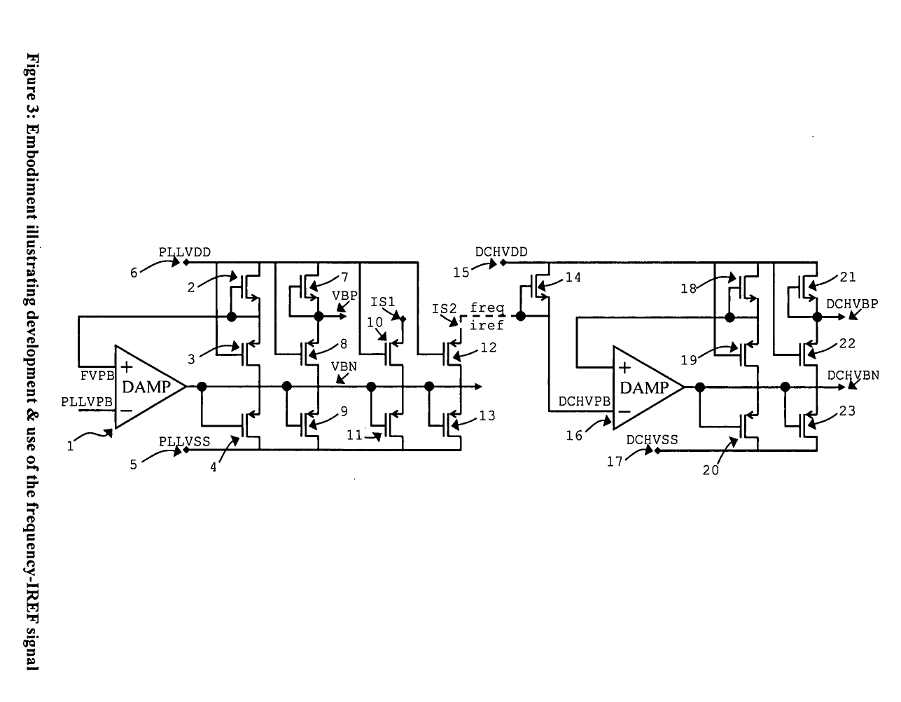

The invention architecture illustrated in FIG. 2 employs an open-loop delay-locked line (Open-Loop DLL or OLDLL) instead of a full DLL to generate sub-cycle clock edges at each data channel. Each of the OLDLL's receives information from the primary phase-locked loop that receives the synchronization clock in the link. In one embodiment of the invention, this frequency information is transmitted as a current source signal to each OLDLL. The current source signal, referred to as a frequency-current-reference or ‘freq_iref’ is employed at the OLDLL to create local bias voltages, referenced to the local supply rails, that are then employed to modulate the delay value of the delay stages of a voltage-controlled delay line (VCDL). By employing exactly the same bias generation circuitry at both the PLL and the OLDLL's, and using delay stages in the OLDLL's that are ratioed or matched with respect to the delay stages in the PLL, the delay ratio between a delay stage at the OLDLL and a delay stage at the PLL is maintained constant over the entire frequency range of the wideband PLL. As the frequency output from the PLL changes, the freq_iref value changes and OLDLL stage delays change correspondingly, thus maintaining the angular relationship of clock edges output by the various stages of the OLDLL to the input clock that is received from the PLL.

With reference to FIG. 2, node pair 1 is the input clock (differential clock in this embodiment) referred to as the ‘source clock’ into the Wideband PLL labeled 2. An output of the PLL is a freq_iref signal 3 that accompanies the clock signal 4 called PHY_Clock distributed to the various data channels that include open-loop delay-locked lines 5.

Note that signal 4 or PHY_Clock (with reference to the embodiment of FIG. 2) implicitly contains frequency information as the inverse of the time period separation between consecutive signal transitions of the same polarity. The use of this implicit frequency information at each of the data channels involves the employment of full DLL's, that include edge-difference or phase detectors, charge pumps and loop filters. The explicit transmission of the frequency information as signal 3, or freq_iref, simplifies data channel clocking design considerably in the invention, essentially including a data channel's local delay line functionality as an extension of the wideband PLL functionality, avoiding the creation of a second electronic control loop.

The transmission of frequency information as a current value is appropriate for two fundamental reasons. Firstly, in most controlled delay-line based PLL's or DLL's, delay control is accomplished by means of current flow into and out of capacitors. In CMOS integrated circuit embodiments of PLL's and DLL's, these capacitors are formed by gate-oxide capacitance of transistor devices. The gate-oxide thickness (and consequently, gate capacitance) is one of the best-controlled parameters of a CMOS fabrication process. This ensures that a capacitor formed from a transistor device located in one region of an integrated chip (IC) and a similar capacitor formed at another location in the IC will be matched very closely in capacitance value. Hence the transmission of the delay-modulating current from a region of the IC to another region of the IC, where delays are generated by the flow of such current into and out of transistor capacitance constructs, ensures that delay-matching is as accurate as can be accomplished despite fabrication and processing variations. Secondly, a current transmitted from one portion of the chip to another, in the absence of any other intervening signal connection, appears at the destination as exactly the same value as that transmitted. This is because the current flow is generated by bias voltages at the transmitting location largely independent of the voltage on the node connecting between the transmitting location and the receiving location, and in accordance with Kirchoff's current summation law, the current flow at the receiver must equal that provided by the transmitter, regardless of the operating supply voltage differences between the two locations. Additionally, a current signal at the receiver generates local bias voltages that sustain the current at the receiver regardless of the variations in device properties at the receiver with respect to devices at the transmitter. Therefore a current signal is better suited to transmitting information than a voltage signal that necessarily requires the transmission of a companion reference signal. This is better understood through an examination of an embodiment illustrating current reference generation circuits at the transmitter and bias generation at the receiver as in FIG. 3.

With reference to FIG. 3, that illustrates an embodiment of the invention architecture applied to a self-biased PLL and tracking OLDLL's, devices 1, 2, 3 and 4 form a voltage-bias generating feedback loop that develops a current through a first stack of devices 2, 3 and 4 corresponding to the reference voltage signal PLLVPB supplied as input to amplifier 1, which reference voltage is developed within the PLL in accordance with the frequency of operation desired. Nodes 5 and 6, PLLVSS and PLLVDD respectively, are local power supply nodes. Devices 2 through 4 form a sub-circuit device stack, called a ‘half-replica stack’, that replicates the functionality of one branch of a typical differential delay stage, emulating current flow through that branch when its control transistor device is directed to permit full current flow through it. The output of amplifier 1 also drives transistor 9, of the stack of devices formed by devices 7, 8 and 9, with this second stack of devices matched exactly with devices 2, 3 and 4 respectively. This mirroring permits the second stack of devices to attain the same current flow through it as the first stack containing devices 2, 3 and 4, while differing in its response to noise from the first stack. This differentiation in noise response allows the second stack to match with the behavior of the differential delay stages of the PLL while generating the necessary bias voltages at nodes VBP and VBN in the figure. Signals VBP and VBN provide driving bias voltages to load and tail current devices in the PLL voltage-controlled oscillator's differential delay stages. Again, with reference to FIG. 3, devices 10 and 11 as well as 12 and 13 form ‘mirror-half-stack's’ that mirror the current flowing in the first two half-replica stacks accurately. This mirroring ratio is made exact by matching devices 4, 9, 11 and 13 very closely, both electrically and physically, with each other. Nodes IS1 and IS2 are now the origination points of current sources that provide an accurate indication of the operating condition (or frequency) of the PLL.

Node IS2 is connected to device 14 in an OLDLL bias generation circuit, located in a different region of the IC integrating the PLL and OLDLL's, with this connection made through signal ‘freq_iref’ as shown in FIG. 3. The operating power supply voltages at the OLDLL location are DCHVDD and DCHVSS at nodes 15 and 17 respectively, where these supply potentials may be different from the supply voltages at the PLL. In a manner akin to the development of bias signal VBP in the second device stack formed by devices 7, 8 and 9, signal DCHVPB, and further, signal DCHVBP are developed through the connection of node IS2 to device 14, with the differences being the length of the connection between devices 12 and 14 and the difference between operating power supplies PLLVDD and DCHVDD. It will be evident to one skilled in the art that both these differences are of no consequence to the current flow, and hence the PLL frequency information is transmitted to the OLDLL location accurately regardless of the physical distance of the OLDLL from the PLL on the IC. It will also be evident that many half-stack's such as the one generating IS2 and the freq_iref signal may be associated with the PLL, thus permitting one PLL to provide it's frequency information through current references to a large number of OLDLL's distributed around the IC.

The current reference freq iref signal in combination with device 14 in FIG. 3 generates signal DCHVPB and local bias voltages DCHVBP and DCHVBN in exactly the same manner as they are generated at the PLL using an identical bias-generation feedback loop. Devices 14, 18 and 21 are matched closely, electrically and physically, with each other as well as to the load devices of the delay stages employed in the OLDLL, and devices 20 and 23 are similarly matched to each other and to the tail current devices of the OLDLL delay stages. Device 14 (and by association, 18 and 21) may not be the same size as devices 2 and 7 at the PLL, allowing for a measure of scaling of the delay and bandwidth of the OLDLL delay stages with respect to the delay stages at the PLL. Alternately, devices 11 and 13 of FIG. 3 may be scaled with respect to devices 4 and 9, thus transmitting a scaled value of current to data receiver OLDLL's.

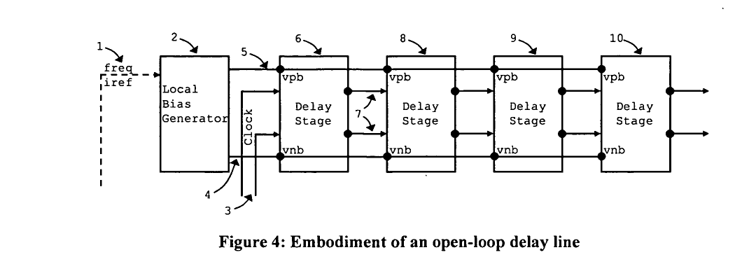

FIG. 4 illustrates in a block-diagrammatical manner an embodiment of an OLDLL. With reference to this figure, signal 1 is a freq_iref signal that produces load and tail-current bias signals VNB and VPB on nodes 4 and 5 respectively. Signal wires 3 form a differential input clock signal feeding into a delay line consisting of differential delay stages 6, 8, 9 and 10. Output wire pair 7 is the delayed output of differential delay stage 6 that is then fed to the next delay stage 8. The output of the chain of delay stages is not fed back to a phase comparator, thereby making this an open-loop delay line with voltage-based control.

It will be evident to one skilled in the art that the output of a delay chain as illustrated in FIG. 4 could be looped back as input into the first delay stage as is done in a typical VCO, resulting in a local VCO that will be closely matched in frequency with the primary PLL. Such an architecture may be employed, for example, to generate reduced-jitter clock distributions within a relatively large integrated circuit by having local VCO's generate clocks locally and by shorting the outputs of the VCO's together in a global clock grid, where the grid may also be designed such that it's self-resonance frequency is very close to the clock frequency.

In order that the OLDLL delay stages track the operating frequency of the primary PLL accurately over the entire range of the PLL, it is important that the delay stages in the OLDLL are exactly the same in architecture as delay stages in the PLL. The load, control and tail current devices, as in a typical delay stage, may be ratioed in size with respect to the same devices in the PLL delay stages to provide a scaled delay. In one embodiment, the load and tail current devices of the OLDLL delay stages are doubled in their respective widths while the control devices remained identical with respect to the same devices in the primary PLL delay stages. This provided approximately one-half the delay of the PLL delay stage as the delay value in a stage of the OLDLL, and this ratio remained essentially constant, independent of operating voltage, temperature and processing variations throughout a decade-wide operating frequency range.

The OLDLL phase outputs (delayed clock edges) may be employed in any fashion desired to recover data in the data receiver channels. Oversampling techniques may be employed, for example, to determine where data transitions occur. A preferred embodiment employs a phase interpolator comprising of mixer circuits and low-swing to full-swing amplifiers to generate fine phase positions numbering 16 within one clock cycle. In this embodiment, the data receiver channel circuits include a ‘bang-bang’ data recovery loop that identifies an optimally placed clock edge among the 16 edges generated from the phase interpolator to best sample the received data. Such a data recovery loop tests each sub-cycle clock edge sequentially to locate the two edges that straddle the optimal data sampling point (approximately the middle of the data ‘eye’) and alternates the data sampling clock between these two phase positions. This search for the optimal edge is typically terminated after the loop determines these two phase clocks, choosing one as the sampling clock. Because the loop scans among the 16 phase clocks to determine the optimal sampling clock, it is not critical that the 16 phase clock's exactly span the duration of one cycle of the primary clock. In other words, the separation between the phase clocks need not be exactly 1/16^{th} of the primary clock period. Therefore mismatches in the delay values of the delay stages of the OLDLL with delay stages of the primary PLL are rendered largely inconsequential with respect to the link bit error rate. This is also the case for an oversampling data recovery loop employed in an embodiment of the invention.

Although specific embodiments are illustrated and described herein, any circuit arrangement configured to achieve the same purposes and advantages may be substituted in place of the specific embodiments disclosed. This disclosure is intended to cover any and all adaptations or variations of the embodiments of the invention provided herein. All the descriptions provided in the specification have been made in an illustrative sense and should in no manner be interpreted in any restrictive sense. The scope, of various embodiments of the invention whether described or not, includes any other applications in which the structures, concepts and methods of the invention may be applied. The scope of the various embodiments of the invention should therefore be determined with reference to the appended claims, along with the full range of equivalents to which such claims are entitled. Similarly, the abstract of this disclosure, provided in compliance with 37 CFR §1.72(b), is submitted with the understanding that it will not be interpreted to be limiting the scope or meaning of the claims made herein. While various concepts and methods of the invention are grouped together into a single ‘best-mode’ implementation in the detailed description, it should be appreciated that inventive subject matter lies in less than all features of any disclosed embodiment, and as the claims incorporated herein indicate, each claim is to viewed as standing on it's own as a preferred embodiment of the invention.

What is claimed is:

1. An integrated circuit apparatus for data recovery, comprising:
a clock generation circuit generating an output clock and a plurality of current reference signals corresponding in value to the frequency of the output clock;
a delay chain within each data receiver, receiving the output clock as well as a current reference signal from the clock generation circuit and modulating delay values of its stages in accordance with the current reference value, generating a plurality of delayed clock signals;
and a data recovery circuit within each data receiver employing the plurality of delay chain clock signals to sample the data signal received.

2. The apparatus of claim 1 where the clock generation circuit is a phase-locked loop.

3. The apparatus of claim 1 where the clock generation circuit is a self-biased phase-locked loop receiving a source clock covering the frequency range from 25 MHz to 350 MHz and generating an output clock that is 10 times the frequency of the source clock.

4. The apparatus of claim 1 where the clock generation circuit is a phase-locked loop comprising of a voltage-controlled oscillator with a plurality of delay stages, and the delay chains within data receivers comprise of delay stages of exactly the same circuit architecture as that of the delay stages in the voltage-controlled oscillator of the phase-locked loop.

5. The apparatus of claim 1 fabricated in a CMOS fabrication process and employing a self-biased phase-locked loop for clock generation, where NFET devices of an additional half-replica stack, forming a mirror-half-stack in the bias generator sub-circuit of the phase-locked loop generate the current reference signal that connects to the PFET device of the same half-replica stack located in the bias generation circuit of a delay chain at a data receiver channel.

6. The apparatus of claim 1 employing an open-loop delay chain in a data receiver.

7. The apparatus of claim 1 employing a phase interpolator generating additional phase clocks in a data receiver.

8. The apparatus of claim 1 employing a bang-bang data recovery loop in the data receiver.

9. The apparatus of claim 1 employing oversampling data recovery in a data receiver.

10. The apparatus of claim 1 where the currents flowing between power supply nodes in any delay stage of a delay chain at a data receiver is equal to the current flowing between power supply nodes in a delay stage of the clock generator.

11. The apparatus of claim 1 where the currents flowing between power supply nodes in any delay stage of a delay chain at a data receiver is not equal to the current flowing between power supply nodes in a delay stage of the clock generator and the ratio between these currents remains constant over the range of operating frequencies.

12. The apparatus of claim 1 employing closed-loop delay chains to generate clock signals of the same frequency as the clock generation circuit.

13. The apparatus of claim 1 employing closed-loop delay chains generating clock signals of the same frequency as the clock generation circuit, with the outputs of the closed-loop delay chains connected to each other through a shorting clock grid.

14. The apparatus of claim 1 employed in multimedia data communications links such as DVI, HDMI and other similar links.

15. Electronic systems comprised of various integrated and discrete electronic circuits and devices that employ the apparatus of claim 1 in any embodiment.

16. Interconnect systems comprised of various integrated and discrete electronic circuits, devices and interconnecting materials and elements that employ the apparatus of claim 1 in any embodiment.
